(19) United States
(12) Patent Application Publication
(10) Pub. No.: US 2007/0160237 A1
(43) Pub. Date: Jul. 12, 2007

(54) Amplifier apparatus and acoustic system

(75) Inventors: Masayuki Hibino, Kanagawa-ken (JP); Tadashi Morikawa, Kanagawa-ken (JP)

Correspondence Address: PEARNE & GORDON LLP, 1801 EAST 9TH STREET, SUITE 1200, CLEVELAND, OH, 44114-3108, US

(73) Assignee: MATSUSHITA ELECTRIC INDUSTRIAL CO., LTD., Osaka (JP)

(21) Appl. No.: 10/597,789

(22) PCT Filed: Feb. 4, 2005
(86) PCT No.: PCT/JP05/01686

§ 371 Date: Aug. 8, 2006

(30) Foreign Application Priority Data
Feb. 9, 2004 (JP) 2004-032089

(51) Int. Cl. H03F 21/00; H04B 1/00

(52) U.S. Cl. 381/119; 381/120

(57) ABSTRACT

It is an object of the present invention to provide an amplifier apparatus which can amplify the sound signal at a relatively high quality, and to provide an acoustic system comprising the amplifier apparatus. The amplifier apparatus comprises a first amplifier 13 having a first acoustic gain, and being adapted to amplify an analog sound signal according to the first acoustic gain, and to allow the first acoustic gain to be changed, an analog-to-digital converter 14 for converting the amplified analog sound signal to a digital sound signal, a second amplifier 15 having an second acoustic gain, being adapted to amplify the digital sound signal according to the second acoustic gain, and to allow the second acoustic gain to be changed, and a controller 16 for obtaining a combined acoustic gain from the first and second acoustic gains, and keeping the combined acoustic gain constant by modifying the second acoustic gain in response to a change of the first acoustic gain.

### TECHNICAL FIELD OF THE INVENTION

The present invention relates to an amplifier apparatus having an acoustic gain to be changed by audio mixers, the amplifier apparatus being adapted to amplify an analog sound signal received from a microphone in a broadcast studio, a multipurpose hall or the like, and an acoustic system comprising the amplifier apparatus.

### DESCRIPTION OF THE RELATED ART

As a conventional acoustic system to be used in, for example, a broadcast studio and a multipurpose hall, there has been known an acoustic system which comprises a head amplifier for amplifying an analog sound signal received from a microphone, an analog-to-digital converter for converting the amplified analog sound signal to a digital sound signal to be outputted to an audio mixer, and a controlling apparatus for adjusting an acoustic gain of the head amplifier (See patent document 1).

In the broadcast studio or the multipurpose hall having two audio mixers located therein, the acoustic system 5, as shown in FIG. 6, further comprises an analog distributor 52 for receiving an analog sound signal from a microphone 51, and producing two analog sound signals to be outputted to the audio mixers 50a and 50b through head amplifiers 53a and 53b and analog-to-digital converters 54a and 54b. The head amplifiers 53a and 53b are adapted to amplify the analog sound signals received from the analog distributor 52, and to output the amplified analog sound signal to the analog-to-digital converters 54a and 54b. The analog-to-digital converters 54a and 54b are adapted to receive the amplified analog sound signals from the head amplifiers 53a and 53b, and to convert the received analog sound signals to digital sound signals to be respectively outputted to the audio mixers 50a and 50b.

Patent document 1: Jpn. unexamined patent publication No. 9-135135 (page 3, FIG. 1)

### DISCLOSURE OF THE INVENTION

### Problems to be Solved by the Invention

The above-mentioned conventional acoustic system, however, encounters such a problem that the analog sound signal to be received by each of the head amplifiers tends to be deteriorated by reason that the analog sound signal is distributed by the analog distributor to each of the head amplifiers through a relatively long analog transmission line.

It is, therefore, an object of the present invention to provide an amplifier apparatus which can process the analog sound signal at a relatively high quality with no analog distributor, and to provide an acoustic system comprising the amplifier apparatus.

### MEANS FOR SOLVING THE PROBLEMS

The amplifier apparatus according to the present invention, comprises: first amplifying means for amplifying an analog sound signal according to a first acoustic gain; converting means for converting the amplified analog sound signal to a digital sound signal; second amplifying means for amplifying, according to a second acoustic gain, the digital sound signal converted by the converting means; and controlling means for obtaining a combined acoustic gain from the first and second acoustic gains, and keeping the combined acoustic gain constant by modifying the second acoustic gain in response to a change of the first acoustic gain.

The amplifier apparatus thus constructed according to the present invention can output the digital sound signal to the audio mixers from the analog-to-digital converter at a relatively high quality.

The acoustic system according to the present invention, comprises: a plurality of audio mixers; and at least one amplifier apparatus for outputting digital sound signals to the audio mixers, the amplifier apparatus including first amplifying means for amplifying an analog sound signal according to a first acoustic gain, converting means for converting the amplified analog sound signal to a digital sound signal, second amplifying means for amplifying, according to a second acoustic gain, the digital sound signal converted by the converting means, a plurality of third amplifying means for amplifying, according to respective third acoustic gains, the digital sound signal amplified by the second amplifying means, and controlling means for obtaining a combined acoustic gain from the first and second acoustic gains, and keeping the combined acoustic gain constant by modifying the second acoustic gain in response to a change of the first acoustic gain, wherein the converting means is adapted to output the converted digital sound signal to one of the audio mixers, the third amplifying means is adapted to output the amplified digital sound signals to the remaining audio mixers, said one audio mixer is adapted to output to the controlling means a control signal indicative of an instruction to change the first acoustic gain, and to allow the controlling means to obtain a combined acoustic gain from the first and second acoustic gains, and to keep the combined acoustic gain constant by modifying the second acoustic gain in response to a change of the first acoustic gain, and each of the remaining audio mixers is adapted to output to the controlling means a control signal indicative of an instruction to change the third acoustic gain, and to allow the controlling means to change the third acoustic gain of the third amplifier.

The acoustic system thus constructed according to the present invention can output the digital sound signal to the audio mixers at a relatively high quality, and allow the acoustic gain of the amplifier to be changed by each of the audio mixers.

The acoustic system according to the present invention, comprises: a plurality of audio mixers; and at least one amplifier apparatus for outputting digital sound signals to the audio mixers, wherein the amplifier apparatus includes first amplifying means for amplifying an analog sound signal according to a first acoustic gain, converting means for converting the amplified analog sound signal to a digital sound signal, second amplifying means for amplifying, according to a second acoustic gain, the digital sound signal converted by the converting means, a plurality of third amplifying means for amplifying, according to respective third acoustic gains, the digital sound signal amplified by the second amplifying means, registering means for registering one of the audio mixers as a main mixer, and registering each of the remaining audio mixers as a secondary mixer, and controlling means for preventing the second and third acoustic gains from being changed by said one audio mixer, having said one audio mixer receive the digital sound signal from the converting means, obtaining a combined acoustic gain from the first and second acoustic gains, keeping the combined acoustic gain constant by modifying the second acoustic gain in response to a change of the first acoustic gain, and having the remaining audio mixers receive the respective digital sound signals from the third amplifying means.

The acoustic system thus constructed according to the present invention can allow one of the audio mixers to be set as an audio mixer which is capable of changing the first acoustic gain of the first amplifier, and allow each of the audio mixers to change the acoustic gain.

In the acoustic system according to the present invention, the controlling means includes a detecting unit for detecting the change of the first acoustic gain, and a judging unit for judging whether or not the first acoustic gain is changed on the basis of information obtained from the detecting unit, starting to compute an elapsed time when the judgment is made that the first acoustic gain is changed, and judging whether or not the computed elapsed time exceeds a predetermined value. The controlling means is adapted to allow the second acoustic gain to be modified in response to the change of the first acoustic gain when the judgment is made by the judging unit that the computed elapsed time exceeds the predetermined value.

The acoustic system thus constructed according to the present invention can keep the sum of the first and second acoustic gains constant even if the main mixer changes the first acoustic gain.

### ADVANTAGEOUS EFFECT OF THE INVENTION

Each of the amplifier apparatus and the acoustic system provided with the amplifier apparatus can process the analog sound signal at a relatively high quality with no analog distributor by reason that the amplifier apparatus comprises first amplifying means having a first acoustic gain, the first amplifying means being adapted to amplify the analog sound signal according to the first acoustic gain, converting means for converting the amplified analog sound signal to a digital sound signal, second amplifying means having a second acoustic gain, the second amplifying means being adapted to amplify, according to the second acoustic gain, the digital sound signal converted by the converting means, and controlling means for obtaining a combined acoustic gain from the first and second acoustic gains, and keeping the combined acoustic gain constant by modifying the second acoustic gain in response to a change of the first acoustic gain.

### BRIEF DESCRIPTION OF THE DRAWINGS

FIG. 1 is a block diagram showing the construction of the first embodiment of the amplifier apparatus and the acoustic system according to the present invention.

FIG. 2 is a schematic view showing the construction of the first embodiment of the acoustic system according to the present invention.

FIG. 3 is a flow chart showing the operation of the first embodiment of the amplifier apparatus and the acoustic system according to the present invention.

FIG. 4 is a block diagram showing the construction of the second embodiment of the amplifier apparatus and the acoustic system according to the present invention.

FIG. 5 is a block diagram showing the construction of the third embodiment of the amplifier apparatus and the acoustic system according to the present invention.

FIG. 6 is a block diagram showing the construction of the conventional acoustic system.

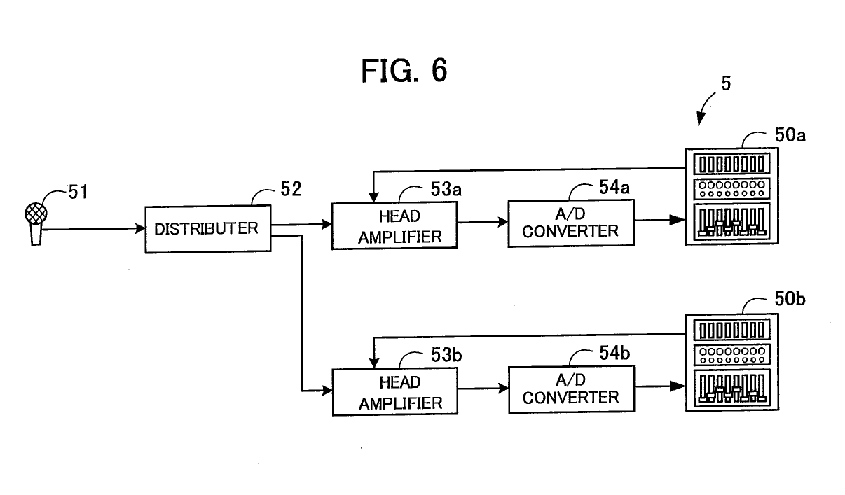

### EXPLANATION OF THE REFERENCE NUMERALS

1, 2, 3 acoustic system
10a, 10b, 10c audio mixer
11 microphone
12 amplifier apparatus
13 first amplifier
14 analog-to-digital converter
15 second amplifier
16 controller
16a detecting unit
16b judging unit
17b, 17c third amplifier
20a, 20b, 20c audio mixer
21 microphone
22 amplifier apparatus
23 first amplifier
24 analog-to-digital converter
25 second amplifier
27a, 27b, 27c third amplifier
26 controller
26a detecting unit
26b judging unit
26c setting unit
30a, 30b, 30c audio mixer
31 microphone
32 amplifier apparatus
33 first amplifier
34 analog-to-digital converter
35 second amplifier
36 controller
36a detecting unit
36b judging unit
36c setting unit
37a, 37b, 37c third amplifier

### DESCRIPTION OF THE PREFERRED EMBODIMENTS

The first embodiment of the amplifier apparatus and the acoustic system according to the present invention will be described hereinafter with reference to the accompanying drawings.

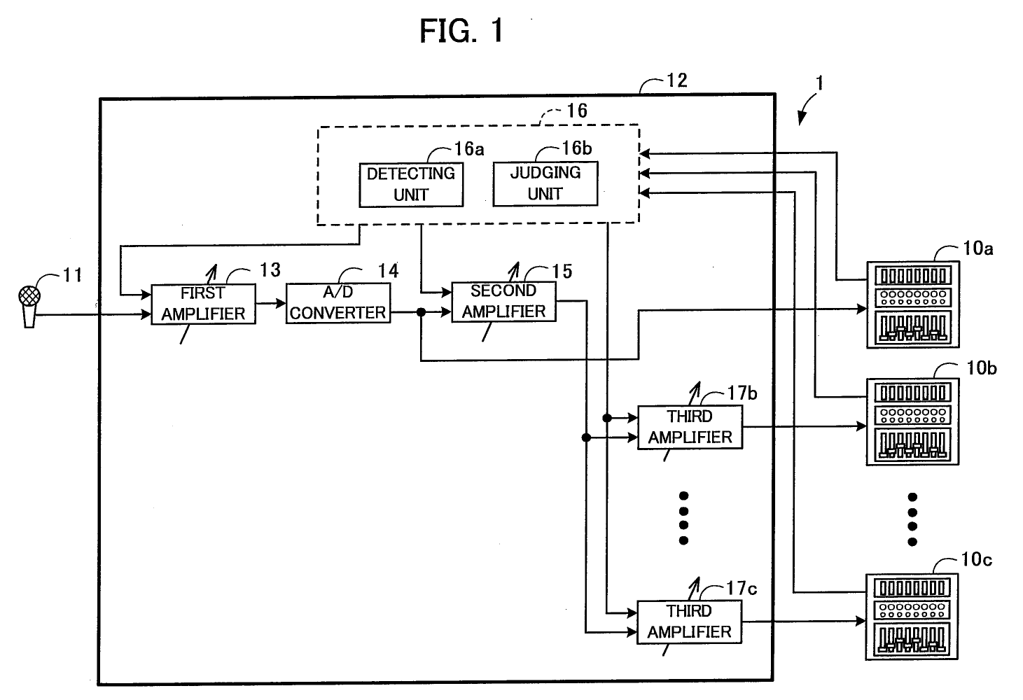

FIG. 1 is a block diagram showing the construction of the amplifier apparatus and the acoustic system according to the first embodiment of the present invention.

As shown in FIG. 1, the acoustic system 1 comprises a plurality of audio mixers 10a, 10b, and 10c, a microphone 11 for converting a sound to an analog sound signal, and an amplifier apparatus 12 for amplifying the analog sound signal outputted by the microphone 11.

The amplifier apparatus 12 includes a first amplifier 13 having a first acoustic gain which is variable, the first amplifier 13 being adapted to amplify the converted analog sound signal according to the first acoustic gain, an analog-to-digital converter 14 for converting the amplified analog sound signal to a digital sound signal, a second amplifier 15 having a second acoustic gain which is variable, the second amplifier 15 being adapted to amplify, according to the second acoustic gain, the digital sound signal converted by the analog-to-digital converter 14, a controller 16 for obtaining a combined acoustic gain from the first and second acoustic gains, and keeping the combined acoustic gain constant by modifying the second acoustic gain in response to a change of the first acoustic gain, and third amplifiers 17b and 17c having respective third acoustic gains which is variable, the third amplifiers 17b and 17c being adapted to amplify, according to the third acoustic gains, the digital sound signal amplified by the second amplifier 15.

The controller 16 includes a detecting unit 16a for detecting the change of the first acoustic gain, a judging unit 16b for judging whether or not the first acoustic gain is changed on the basis of information obtained from the detecting unit 16a, starting to compute an elapsed time when the judgment is made that the first acoustic gain is changed, and judging whether or not the computed elapsed time exceeds a predetermined value. The controller 16 is adapted to allow the second acoustic gain to be changed in response to the change of the first acoustic gain when the judgment is made by the judging unit 16b that the computed elapsed time exceeds the predetermined value.

When the audio mixer 10a outputs a control signal to the controller 16, the control signal being indicative of an instruction to change an acoustic gain, the controller 16 is adapted to change the first acoustic gain of the first amplifier 13 by controlling the first amplifier 13 in response to the control signal received from the audio mixer 10a. When the audio mixer 10b outputs a control signal to the controller 16, the control signal being indicative of an instruction to change an acoustic gain, the controller 16 is adapted to change the third acoustic gain of the third amplifier 17b by control the third amplifier 17b in response to the control signal received from the audio mixer 10b. When the audio mixer 10c outputs produce a control signal to the controller 16, the control signal being indicative of an instruction to change an acoustic gain, the controller 16 is adapted to change the third acoustic gain of the third amplifier 17c by control the third amplifier 17c in response to the control signal received from the audio mixer 10c.

Each of the audio mixers 10a, 10b, and 10c includes a plurality of channel units for processing digital sound signals. Each of the channel units has a control signal producing unit for producing a control signal indicative of an instruction to the amplifier apparatus 12 to change an acoustic gain.

The simple example of the acoustic system 1 according to the present invention is shown in FIG. 1 for easier comprehension. In this embodiment, the amplifier apparatus 12 comprises a microphone 11, an amplifier apparatus 12, and a plurality of audio mixers 10a, 10b, and 10c. However, the practical acoustic system may comprise a plurality of amplifier apparatuses 12, the number of the amplifier apparatuses 12 depending on the number of analog sound signals, the number of the third amplifiers 17a, 17b, and 17c depending on the number of the audio mixers 10a, 10b, and 10c.

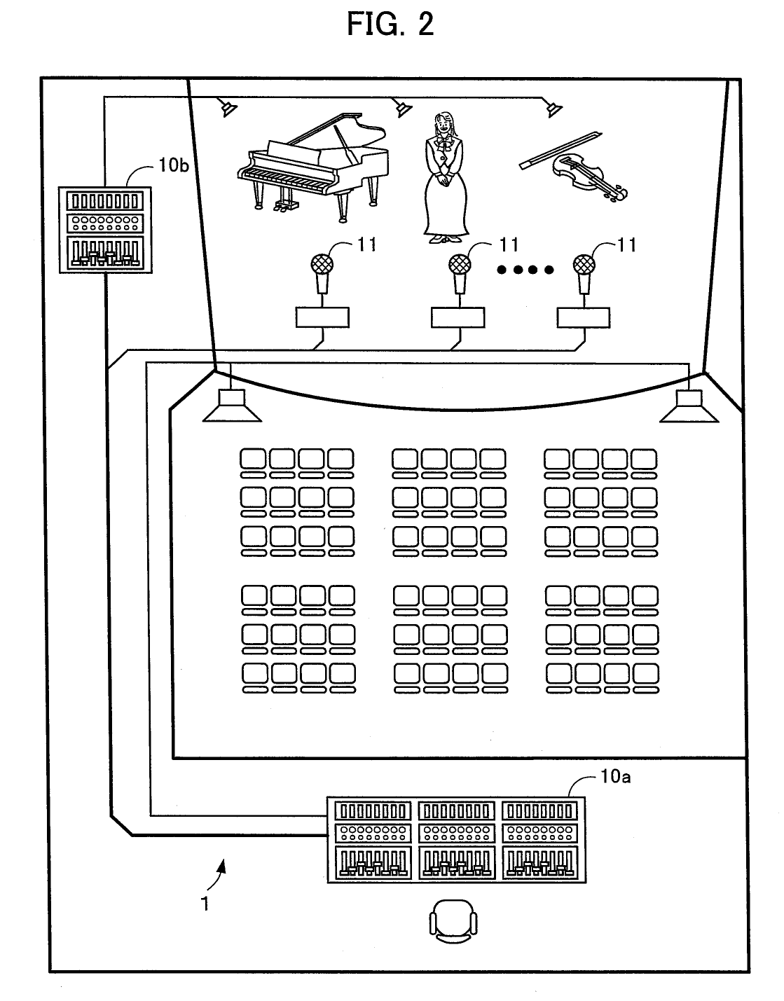

FIG. 2 is a schematic view showing, as an example, the construction of the acoustic system installed in a multipurpose hall.

As shown in FIG. 2, the acoustic system 1 comprises an audio mixer 10a for processing sound signals received from microphones 11, and outputting the processed sound signals to loudspeakers to ensure that sounds represented by the sound signals are outputted toward audiences, an audio mixer 10b to be used as a monitor, the audio mixer 10b being adapted to process the sound signals received from the microphones 11 to ensure that sounds represented by the processed sound signals is outputted by loudspeakers located in the vicinity of musical performers.

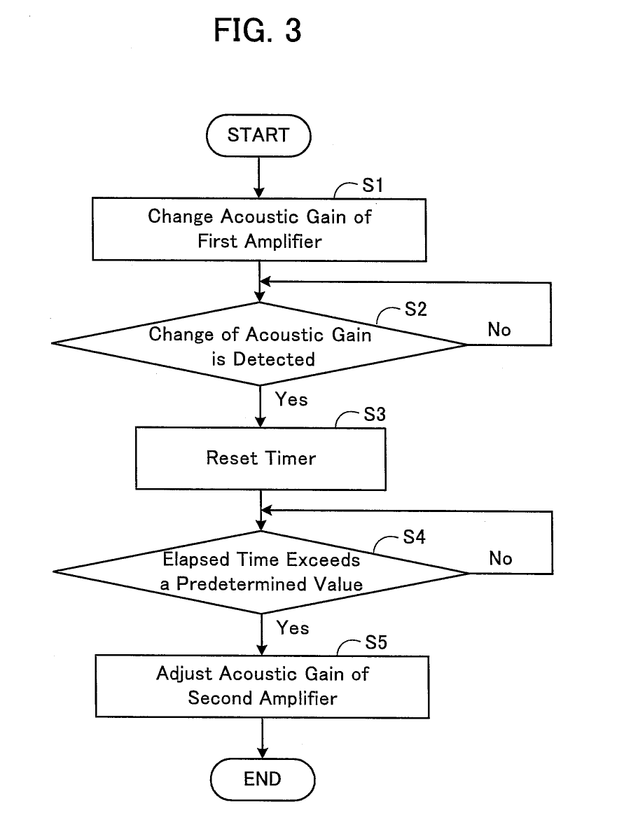

The operation of the amplifier apparatus and the acoustic system according to the first embodiment of the present invention will be then described hereinafter with reference to FIGS. 1 and 3.

When the control signal indicative of the instruction to change an acoustic gain is inputted in the controller 16 by the audio mixer 10a which is electrically connected as a main mixer to the amplifier apparatus 12, the first acoustic gain of the first amplifier 13 is changed by the controller 16 (in the step S1). The judgment is then made by the judging unit 16b (in the step S2) on whether or not the controller 16 completes the task of changing the first acoustic gain. When the judgment is made in the step S2 that the controller 16 completes the task of changing the first acoustic gain, the controller 16 resets a timer (not shown), and start to compute the elapsed time (in the step S3). The judgment is made (in the step S4) on whether or not the elapsed time computed by the timer (not shown) exceeds a predetermined value. When the judgment is made that the elapsed time computed by the timer (not shown) exceeds a predetermined value, the controller 16 obtains a combined acoustic gain from the first and second acoustic gains, and keeps the combined acoustic gain constant by modifying the second acoustic gain (in the step S5).

When, on the other hand, the control signal indicative of the instruction to change an acoustic gain is inputted into the controller 16 by the audio mixer 10b which is electrically connected as a secondary mixer to the amplifier apparatus 12, the controller 16 controls the third amplifier 17b related to the audio mixer 10b to change the third acoustic gain in response to the control signal received from the audio mixer 10b. When the control signal indicative of the instruction to change an acoustic gain is inputted into the controller 16 by the audio mixer 10c, the controller 16 controls the third amplifier 17c related to the audio mixer 10c to change the third acoustic gain in response to the control signal received from the audio mixer 10c.

From the above detailed description, it will be understood that the amplifier apparatus and the acoustic system according to the first embodiment of the present invention can produce digital sound signals from an analog sound signal with no analog distributor before transmitting the digital sound signals to the respective audio mixers, allow the acoustic gain to be changed by the audio mixers, and prevent the analog sound signal from being deteriorated by an analog distributor by reason that the amplifier apparatus includes a first amplifier having a first acoustic gain, the first amplifier being adapted to amplify, according to the first acoustic gain, the converted analog sound signal, an analog-to-digital converter for converting the amplified analog sound signal to a digital sound signal, a second amplifier having a second acoustic gain, the second amplifier being adapted to amplify, according to the second acoustic gain, the digital sound signal converted by the analog-to-digital converter, and a controller for obtaining a combined acoustic gain from the first and second acoustic gains, and keep the combined acoustic gain constant by modifying the second acoustic gain in response to the change of the first acoustic gain.

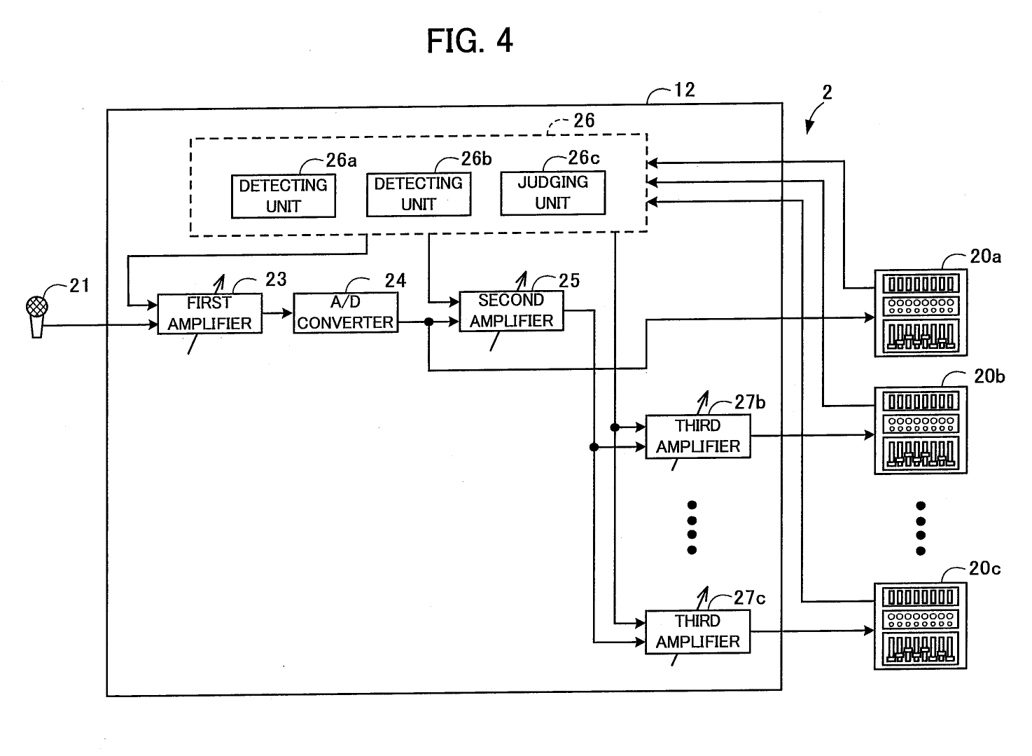

The second embodiment of the amplifier apparatus and the acoustic system according to the present invention will be then described hereinafter with reference to FIG. 4.

As shown in FIG. 4, the acoustic system 2 comprises a plurality of audio mixers 20a, 20b, and 20c, and at least one amplifier apparatus 22 for outputting digital sound signals to the respective audio mixers 20a, 20b, and 20c.

The amplifier apparatus 22 includes a first amplifier 23 having a first acoustic gain, the first amplifier 23 being adapted to amplify an analog sound signal according to the first acoustic gain, an analog-to-digital converter 24 for converting the amplified analog sound signal to a digital sound signal, a second amplifier 25 having a second acoustic gain, the second amplifier 25 being adapted to amplify, according to the second acoustic gain, the digital sound signal converted by the analog-to-digital converter 24, a controller 26 for obtain a combined acoustic gain from the first and second acoustic gains, and keep the combined acoustic gain constant by modifying the second acoustic gain in response to the change of the first acoustic gain, a plurality of third amplifiers 27a, 27b, and 27c respectively having third acoustic gains, the third amplifiers being adapted to amplify, according to the third acoustic gains, the digital sound signal amplified by the second amplifier 25.

The controller 26 includes a detecting unit 26a for detecting the change of the first acoustic gain, a judging unit 26b for judging whether or not the first acoustic gain is changed on the basis of information received from the detecting unit 26a, starting to compute the elapsed time when the judgment is made that the first acoustic gain is changed, and judging whether or not the computed elapsed time exceeds a predetermined value, and a setting unit 26c for registering any one of the audio mixers 20a, 20b, and 20c as a main mixer, and registering the remaining mixers as a secondary mixer. When the judgment is made by the judging unit 26b that the computed elapsed time exceeds the predetermined value, the controller 26 is adapted to obtain a combined acoustic gain from the first and second acoustic gains, and keep the combined acoustic gain constant by controlling the second amplifier 25 in response to the change of the first acoustic gain.

When the control signal indicative of the instruction to change an acoustic gain is inputted into the controller 26 by the audio mixer 20a which is registered as a main mixer by the setting unit 26c, the controller 26 controls the first amplifier 23 to change the first acoustic gain of the first amplifier 23 in response to the control signal received from the audio mixer 20a. When, on the other hand, the control signal indicative of the instruction to change an acoustic gain is inputted into the controller 26 by the audio mixer 20b which is registered as a secondary mixer by the setting unit 26c, the controller 26 controls the third amplifier 27b related to the audio mixer 20b to change the third acoustic gain of the third amplifier 27b in response to the control signal received from the audio mixer 20b. When the control signal indicative of the instruction to change an acoustic gain is inputted into the controller 26 by the audio mixer 20c which is registered as a secondary mixer by the setting unit 26c, the controller 26 controls the third amplifier 27b related to the audio mixer 20c to change the third acoustic gain of the third amplifier 27b in response to the control signal received from the audio mixer 20c.

From the foregoing description, it will be understood that the main mixer can change the first acoustic gain of the first amplifier 23 (equivalent to the head amplifier of the conventional acoustic system), the secondary mixers changes the respective third acoustic gains of the third amplifier 27a, 27b, and 27c without changing the first acoustic gain of the first amplifier 23.

The operation of the amplifier apparatus and the acoustic system according to the second embodiment of the present invention will be described hereinafter.

The steps of the second embodiment of the amplifier apparatus and the acoustic system the same as those of the first embodiment of the amplifier apparatus 12 and the acoustic system 1 will not be described hereinafter. The steps of the second embodiment of the amplifier apparatus and the acoustic system different from those of the first embodiment of the amplifier apparatus 12 and the acoustic system 1 will be described hereinafter.

Any one of the audio mixers 20a 20b, and 20c is firstly registered as a main mixer in the controller 26, while each of the remaining audio mixers 20a 20b, and 20c is registered as a secondary mixer.

When the control signal indicative of an instruction to change an acoustic gain is produced and inputted into the controller 26 by the audio mixer 20a registered the main mixer, the controller 26 is operated to obtain a combined acoustic gain from the first and second acoustic gains, and to change the first acoustic gain, in response to the control signal produced by the audio mixer 20a registered as the main mixer, while keeping the combined acoustic gain constant.

When, on the other hand, the control signal indicative of the instruction to change an acoustic gain is produced and inputted into the controller 26 by the audio mixer 20b registered as the secondary mixer, the controller 26 changes the third acoustic gain of the third amplifier 27b related to the audio mixer 20b in response to the control signal produced by the audio mixer 20b.

From the foregoing description, it will be understood that the amplifier apparatus and the acoustic system according to the second embodiment of the present invention can change the acoustic gain in response to the control signal produced by each of the main and secondary mixers by reason that the amplifier apparatus is provided with a controller for changing the first acoustic gain of the first amplifier by controlling the first amplifier in response to the control signal produced by the audio mixer registered as the main mixer, and changing the third acoustic gain of the third amplifier by controlling the third amplifier in response to the control signal produced by the audio mixer registered as the secondary mixer.

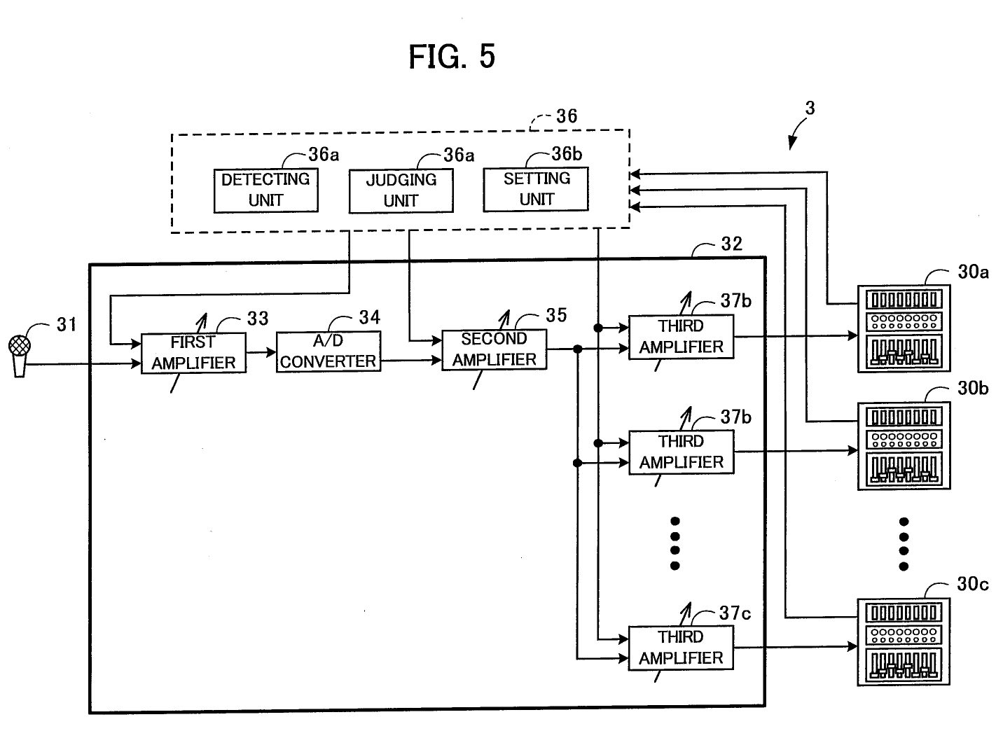

In this embodiment of the acoustic system according to the present invention, the amplifier apparatus 22 includes a controller 26. However, the acoustic system 3 may comprise, as shown in FIG. 5, a plurality of amplifier apparatuses 32, and a controller 36 externalized from the amplifier apparatuses 32. The controller 36 may be adapted to control the amplifier apparatuses 32. In this case, the constitutional elements of each of the amplifier apparatuses 32 is the same as those of the amplifier apparatus 22 shown in FIG. 4 except for the controller 36. Therefore, each of the constitutional elements of the acoustic system 3 will not be described hereinafter.

### INDUSTRIAL APPLICABILITY OF THE PRESENT INVENTION

As will be seen from the foregoing description, each of the amplifier apparatus and the acoustic system according to the present invention has an effect of processing sound signals at a relatively high quality in comparison with the conventional acoustic system in which the analog sound signal is distributed to each of the head amplifiers through the analog distributor. The amplifier apparatus and the acoustic system provided with the above-mentioned amplifier apparatus are useful in a broadcast studio and a multipurpose hall by reason that the amplifier apparatus is adapted to amplify, according to an acoustic gain, an analog sound signal received from a microphone, and to allow the acoustic gain to be changed by the audio mixers.

What is claimed is:

1. An amplifier apparatus, comprising:
first amplifying means for amplifying an analog sound signal according to a first acoustic gain;
converting means for converting said amplified analog sound signal to a digital sound signal;
second amplifying means for amplifying, according to a second acoustic gain, said digital sound signal converted by said converting means; and
controlling means for obtaining a combined acoustic gain from said first and second acoustic gains, and keeping said combined acoustic gain constant by modifying said second acoustic gain in response to a change of said first acoustic gain.

2. An acoustic system, comprising:
a plurality of audio mixers; and
at least one amplifier apparatus for outputting digital sound signals to said audio mixers, said amplifier apparatus including first amplifying means for amplifying an analog sound signal according to a first acoustic gain, converting means for converting said amplified analog sound signal to a digital sound signal, second amplifying means for amplifying, according to a second acoustic gain, said digital sound signal converted by said converting means, a plurality of third amplifying means for amplifying, according to respective third acoustic gains, said digital sound signal amplified by said second amplifying means, and controlling means for obtaining a combined acoustic gain from said first and second acoustic gains, and keeping said combined acoustic gain constant by modifying said second acoustic gain in response to a change of said first acoustic gain, wherein
said converting means is adapted to output said converted digital sound signal to one of said audio mixers,
said third amplifying means is adapted to output said amplified digital sound signals to the remaining audio mixers,
said one audio mixer is adapted to output to said controlling means a control signal indicative of an instruction to change said first acoustic gain, and to allow said controlling means to obtain a combined acoustic gain from said first and second acoustic gains, and to keep said combined acoustic gain constant by modifying said second acoustic gain in response to a change of said first acoustic gain, and
each of said remaining audio mixers is adapted to output to said controlling means a control signal indicative of an instruction to change said third acoustic gain, and to allow said controlling means to change said third acoustic gain of said third amplifier.

3. An acoustic system, comprising:
a plurality of audio mixers; and
at least one amplifier apparatus for outputting digital sound signals to said audio mixers, wherein
said amplifier apparatus includes first amplifying means for amplifying an analog sound signal according to a first acoustic gain, converting means for converting said amplified analog sound signal to a digital sound signal, second amplifying means for amplifying, according to a second acoustic gain, said digital sound signal converted by said converting means, a plurality of third amplifying means for amplifying, according to respective third acoustic gains, said digital sound signal amplified by said second amplifying means, registering means for registering one of said audio mixers as a main mixer, and registering each of the remaining audio mixers as a secondary mixer, and controlling means for preventing said second and third acoustic gains from being changed by said one audio mixer, having said one audio mixer receive said digital sound signal from said converting means, obtaining a combined acoustic gain from said first and second acoustic gains, keeping said combined acoustic gain constant by modifying said second acoustic gain in response to a change of said first acoustic gain, and having said remaining audio mixers receive said respective digital sound signals from said third amplifying means.

4. An acoustic system as set forth in claim 2 or claim 3, in which
said controlling means includes a detecting unit for detecting said change of said first acoustic gain, and a judging unit for judging whether or not said first acoustic gain is changed on the basis of information obtained from said detecting unit, starting to compute an elapsed time when the judgment is made that said first acoustic gain is changed, and judging whether or not said computed elapsed time exceeds a predetermined value,
said controlling means is adapted to allow said second acoustic gain to be modified in response to said change of said first acoustic gain when the judgment is made by said judging unit that said computed elapsed time exceeds said predetermined value.
